(19) United States
(12) Patent Application Publication
(10) Pub. No.: US 2024/0203881 A1
(43) Pub. Date: Jun. 20, 2024

(54) DIELECTRIC SEPARATION FOR BACKSIDE POWER RAIL LINES

(71) Applicant: International Business Machines Corporation, Armonk, NY (US)

(72) Inventors: Chen Zhang, Guiderland, NY (US); Oleg Gluschenkov, Tannersville, NY (US); Junli Wang, Slingerlands, NY (US); Somnath Ghosh, Clifton Park, NY (US); Dechao Guo, Niskayuna, NY (US)

(21) Appl. No.: 18/083,385

(22) Filed: Dec. 16, 2022

(51) Int. Cl. H01L 23/528; H01L 21/8238; H01L 27/092; H01L 29/417

(52) U.S. Cl. CPC H01L 23/5286; H01L 21/823871; H01L 27/092; H01L 29/41725

(57) ABSTRACT

A semiconductor device includes a transistor structure comprising a plurality of source/drain regions. Base portions of the plurality of source/drain regions correspond to a second side of the semiconductor device opposite to a first side of the semiconductor device. A plurality of metal lines are disposed on the second side of the semiconductor device, wherein the plurality of metal lines comprise at least a first metal line and a second metal line. At least one dielectric layer is disposed between the first metal line and the second metal line.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming backside metal lines separated by one or more dielectric layers.

In one embodiment, a semiconductor device includes a transistor structure comprising a plurality of source/drain regions. Base portions of the plurality of source/drain regions correspond to a second side of the semiconductor device opposite to a first side of the semiconductor device. A plurality of metal lines are disposed on the second side of the semiconductor device, wherein the plurality of metal lines comprise at least a first metal line and a second metal line. At least one dielectric layer is disposed between the first metal line and the second metal line.

In another embodiment, a semiconductor device includes a plurality of metal lines disposed on a backside of the semiconductor device. The plurality of metal lines comprise at least a power supply line and a ground line. At least one dielectric layer is disposed between the power supply line and the ground line.

In another embodiment, a semiconductor device includes a transistor structure, wherein a base portion of the transistor structure corresponds to a second side of the semiconductor device opposite to a first side of the semiconductor device. A plurality of conductive lines are disposed on the second side of the semiconductor device. At least one dielectric layer is disposed between at least two conductive lines of the plurality of conductive lines.

These and other features and advantages of embodiments described herein will become more apparent from the accompanying drawings and the following detailed description.

### BRIEF DESCRIPTION OF THE DRAWINGS

FIG. 1 is a schematic cross-sectional view illustrating a semiconductor substrate with channel and buried dielectric layers, according to an embodiment of the invention.

FIG. 2 is a schematic cross-sectional view illustrating patterning to form isolated active regions, according to an embodiment of the invention.

FIG. 3 is a schematic cross-sectional view taken along the line X-X′ in FIG. 2 and illustrating formation of dummy gate regions, according to an embodiment of the invention.

FIG. 4 is a schematic cross-sectional view illustrating removal of portions of the structure from FIG. 3 to expose the semiconductor substrate, according to an embodiment of the invention.

FIG. 5 is a schematic cross-sectional view illustrating growth of source/drain regions on the FIG. 4 structure, according to an embodiment of the invention.

FIG. 6A is a schematic cross-sectional view illustrating formation of replacement gate regions and inter-layer dielectric (ILD) layer formation on the FIG. 5 structure, according to an embodiment of the invention.

FIG. 6B is a schematic cross-sectional view taken along the line A-A′ in FIG. 6A and illustrating ILD layer formation, according to an embodiment of the invention.

FIG. 7A is a schematic cross-sectional view illustrating rotation and attachment of the FIG. 6A structure to another semiconductor substrate, according to an embodiment of the invention.

FIG. 7B is a schematic cross-sectional view taken along the line A-A′ in FIG. 7A and illustrating rotation and attachment of the FIG. 6B structure to the other semiconductor substrate, according to an embodiment of the invention.

FIG. 8A is a schematic cross-sectional view illustrating removal of the original substrate from the FIG. 7A structure, according to an embodiment of the invention.

FIG. 8B is a schematic cross-sectional view taken along the line A-A′ in FIG. 8A and illustrating the removal of the original substrate from the FIG. 7B structure, according to an embodiment of the invention.

FIG. 9A is a schematic cross-sectional view illustrating contact and ILD layer formation on the FIG. 8A structure, according to an embodiment of the invention.

FIG. 9B is a schematic cross-sectional view taken along the line A-A′ in FIG. 9A and illustrating the contact and ILD layer formation on the FIG. 8B structure, according to an embodiment of the invention.

FIG. 10A is a schematic cross-sectional view illustrating formation of a ground line on the FIG. 9A structure, according to an embodiment of the invention.

FIG. 10B is a schematic cross-sectional view taken along the line A-A′ in FIG. 10A and illustrating formation of the ground line on the FIG. 9B structure, according to an embodiment of the invention.

FIG. 11A is a schematic cross-sectional view illustrating dielectric layer formation on the FIG. 10A structure, according to an embodiment of the invention.

FIG. 11B is a schematic cross-sectional view taken along the line A-A′ in FIG. 11A and illustrating the dielectric layer formation on the FIG. 10B structure, according to an embodiment of the invention.

FIG. 12A is a schematic cross-sectional view illustrating removal of portions of the dielectric layer from the FIG. 11A structure, according to an embodiment of the invention.

FIG. 12B is a schematic cross-sectional view taken along the line A-A′ in FIG. 12A and illustrating removal of portions of the dielectric layer from and supply voltage line formation on the FIG. 11B structure, according to an embodiment of the invention.

FIG. 13A is a schematic cross-sectional view illustrating ILD layer formation and formation of an additional layer of ground and supply voltage lines on the FIG. 12A structure, according to an embodiment of the invention.

FIG. 13B is a schematic cross-sectional view taken along the line A-A′ in FIG. 13A and illustrating ILD layer formation and formation of the additional layer of the ground line on the FIG. 12B structure, according to an embodiment of the invention.

FIG. 14A is a schematic cross-sectional view illustrating formation of a ground line and a dielectric layer on the FIG. 9A structure, according to an embodiment of the invention.

FIG. 14B is a schematic cross-sectional view taken along the line A-A′ in FIG. 14A and illustrating formation of the ground line and the dielectric layer on the FIG. 9B structure, according to an embodiment of the invention.

FIG. 15A is a schematic cross-sectional view illustrating supply voltage line formation on the FIG. 14A structure, according to an embodiment of the invention.

FIG. 15B is a schematic cross-sectional view taken along the line A-A′ in FIG. 15A and illustrating removal of portions of the dielectric layer from and supply voltage line formation on the FIG. 14B structure, according to an embodiment of the invention.

FIG. 16A is a schematic cross-sectional view illustrating formation of another dielectric layer on the FIG. 15A structure, according to an embodiment of the invention.

FIG. 16B is a schematic cross-sectional view taken along the line A-A′ in FIG. 16A and illustrating formation of the other dielectric layer on the FIG. 15B structure, according to an embodiment of the invention.

FIG. 17A is a schematic cross-sectional view illustrating formation of a via opening on the FIG. 16A structure, according to an embodiment of the invention.

FIG. 17B is a schematic cross-sectional view taken along the line A-A′ in FIG. 17A and illustrating formation of the via opening on the FIG. 16B structure, according to an embodiment of the invention.

FIG. 18A is a schematic cross-sectional view illustrating formation of another ground line and a via on the FIG. 17A structure, according to an embodiment of the invention.

FIG. 18B is a schematic cross-sectional view taken along the line A-A′ in FIG. 18A and illustrating formation of the other ground line and the via on the FIG. 17B structure, according to an embodiment of the invention.

FIG. 19A is a schematic cross-sectional view illustrating formation of another dielectric layer, another supply voltage line and another via on the FIG. 18A structure, according to an embodiment of the invention.

FIG. 19B is a schematic cross-sectional view taken along the line A-A′ in FIG. 19A and illustrating formation of the other dielectric layer, the other supply voltage line and another via on the FIG. 18B structure, according to an embodiment of the invention.

### DETAILED DESCRIPTION

Illustrative embodiments of the invention may be described herein in the context of illustrative methods for forming power supply and ground lines on a backside of a semiconductor device and at least one dielectric layer disposed between the power supply and ground lines, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (NFET and PFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation complementary FET (CFET) devices may be used. CFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. CFET structures provide improved track height scaling, leading to structural gains (e.g., such as 30-40% structural gains for different types of devices, such as logic devices, static random-access memory (SRAM) devices, etc.). In CFET structures, n-type and p-type nanowires or nanosheets are stacked on each other, eliminating n-to-p separation bottlenecks and reducing the device area footprint. There is, however, a continued to desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation CFET devices.

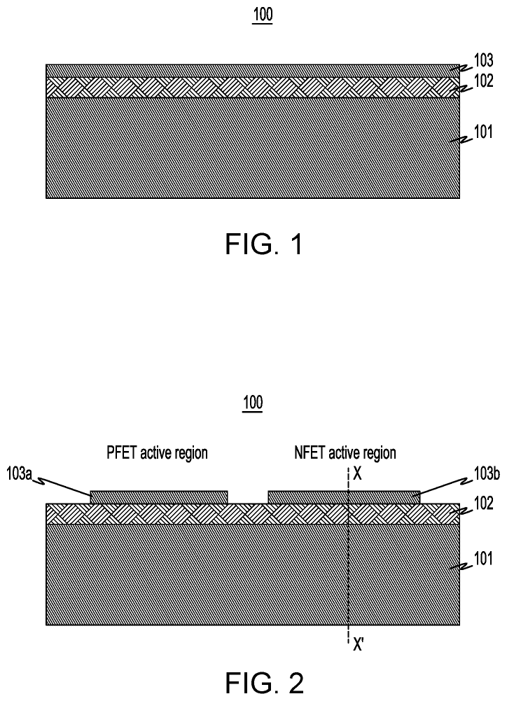

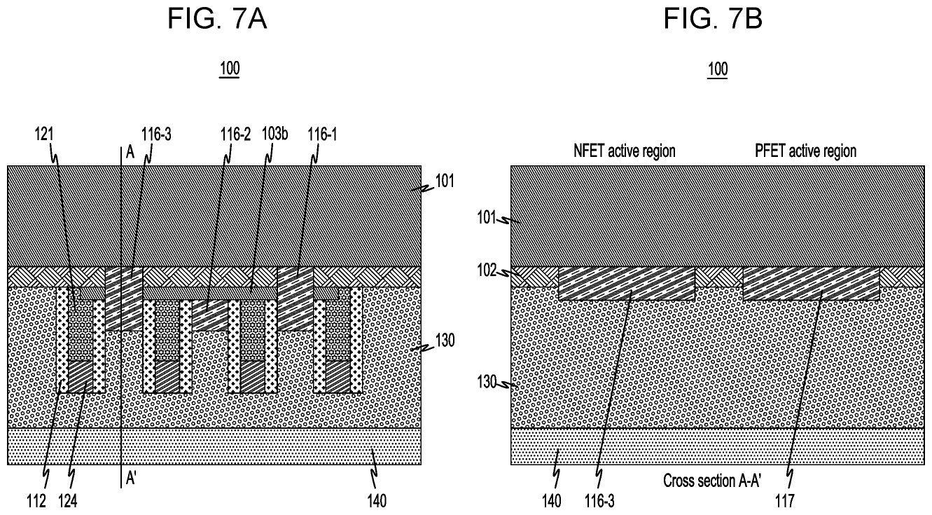

As used herein, “frontside or “first side” refers to a side on top of semiconductor substrate 101 and/or buried dielectric layer 102 in the orientation shown in the cross-sectional views of FIGS. 1-6B, or under the semiconductor substrate 101 and/or buried dielectric layer 102 in the orientation shown in the cross-sectional views of FIGS. 7A-19B. As used herein, “backside” or “second side” refers to a side under the semiconductor substrate 101 and/or buried dielectric layer 102 in the orientation shown in the cross-sectional views of FIGS. 1-6B, or on top of the semiconductor substrate 101 and/or buried dielectric layer 102 in the orientation shown in the cross-sectional views of FIGS. 7A-19B (e.g., opposite the “frontside”).

For example, bottom or base portions of a transistor structure (e.g., bottom or base portions of source/drain regions) correspond to a backside of a semiconductor device, while top or leading end portions of the transistor structure (e.g., top or leading end portions of source/drain regions) correspond to frontside of a semiconductor device.

Referring to FIG. 1, a semiconductor structure 100 comprises a semiconductor substrate 101 including semiconductor material including, but not limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or other like semiconductor. In addition, multiple layers of the semiconductor materials can be used as the semiconductor material of the substrate. In an illustrative embodiment, the semiconductor substrate 101 is a highly doped silicon substrate. A buried dielectric layer 102 (e.g., buried oxide or nitride layer) is formed on the semiconductor substrate 101, and a channel layer 103 is formed on the buried dielectric layer 102. For example, depending on the material of the channel layer 103, the channel layer 103 and the buried dielectric layer 102 comprise, for example, a silicon-on-insulator (SOI), silicon-germanium-on-insulator (SGOI) or III-V-on-insulator configuration. Depending on application, the channel layer 103 can comprise, for example, fins, nanosheets or other channel configurations for a planar transistor.

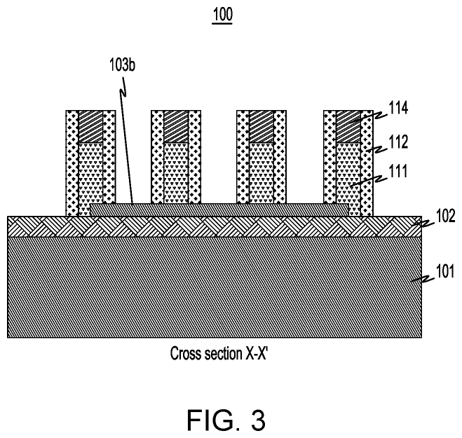

Referring to FIG. 2, the channel layer 103 is patterned into a p-type channel portion 103a and an n-type channel portion 103b to respectively correspond to isolated active regions for a p-type FET (PFET) and an n-type FET (NFET). Patterning may be performed by various patterning techniques, including, but not necessarily limited to, directional etching, a sidewall image transfer (SIT) process, lithography (e.g., extreme ultraviolet (EUV)) in conjunction with reactive ion etching (RIE), self-aligned double patterning (SADP), self-aligned multiple patterning (SAMP), and/or self-aligned quadruple patterning (SAQP)), for example. Although two channel portions 103a and 103b are shown in the figures for ease of explanation, more than two channel portions can be formed. For purposes of explanation, the cross-sections in FIGS. 3-5, 6A, 7A, 8A, 9A, 10A, 11A, 12A, 13A, 14A, 15A, 16A, 17A, 18A and 19A correspond to line X-X′ in FIG. 2, and illustrate operations in an NFET active region. It is to be understood that the same and/or similar operations are performed in the PFET active region.

Referring to FIG. 3, dummy gate regions 111 are formed on the n-type channel portion 103b. The dummy gate regions 111 include, but are not necessarily limited to, amorphous silicon (a-Si). The dummy gate regions 111 are deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular layer deposition (MILD), molecular beam deposition (MBD), pulsed laser deposition (PLD), liquid source misted chemical deposition (LSMCD), sputtering and/or plating, followed by a planarization process, such as, chemical mechanical planarization (CMP), and lithography and etching steps to remove excess dummy gate material, and pattern the deposited layer.

Gate spacers 112 are positioned on opposite lateral sides of the dummy gate regions 111. The gate spacers 112 are formed from a dielectric material including, but not necessarily limited to, silicon oxide (SiOₓ), where x is, for example, 2 in the case of silicon dioxide (SiO₂), or 1.99 or 2.01, or a nitride, such as, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) or other dielectric. The gate spacers 112 can be formed by any suitable techniques such as deposition followed by directional etching. Deposition may include, but is not limited to, ALD or CVD. Directional etching may include but is not limited to RIE. Cap layers 114 comprising, for example, SiN, SiO₂, or combination of SiN and SiO₂, are formed on the dummy gate regions 111.

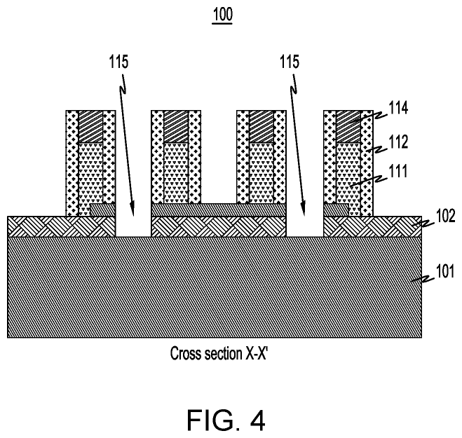

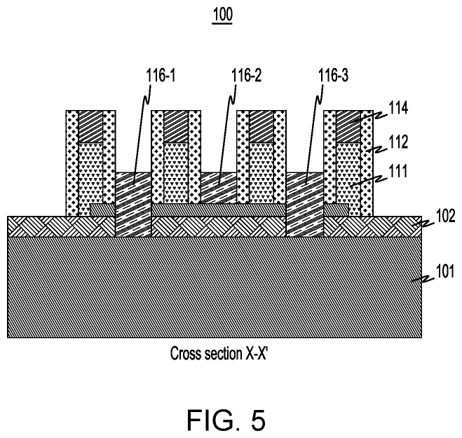

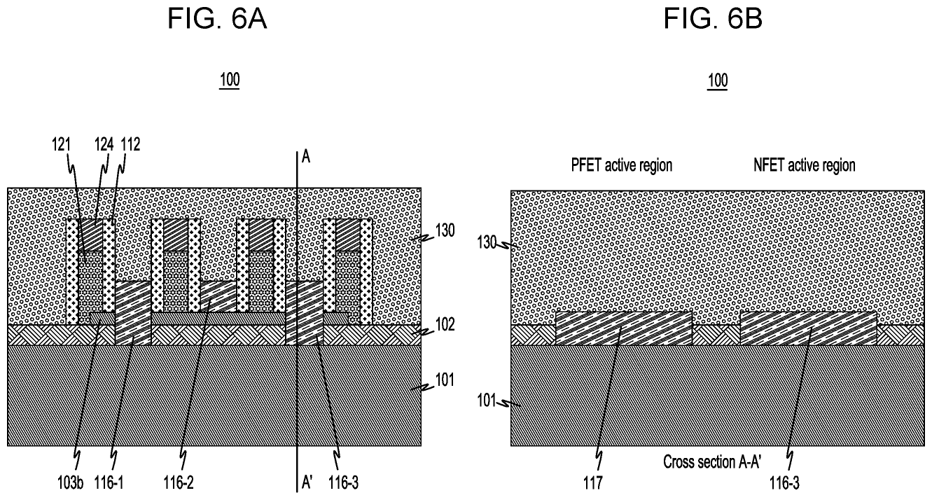

Referring to FIG. 4, portions of the semiconductor structure 100 including parts of the n-type channel portion 103b and parts of the buried dielectric layer 102 are removed to expose parts of the semiconductor substrate 101. The removal can be performed using, for example, etching processes such as, for example, RIE processes. As can be seen FIG. 4, openings 115 exposing the parts of the semiconductor substrate 101 are formed. Referring to FIG. 5, Source/drain regions 116-1 and 116-3 are formed in openings 115 and are epitaxially grown from the semiconductor substrate 101 and the n-type channel portion 103b. The source/drain regions 116-1 and 116-3 are electrically connected to the semiconductor substrate 101. The source/drain region 116-2 is grown from and formed on the n-type channel portion 103b, and is electrically isolated from the source/drain regions 116-1 and 116-3. Although not shown in FIG. 5, source/drain regions are similarly formed in the PFET active region. An example of a source/drain region in the PFET active region (source/drain region 117) is shown in the cross-sectional views of FIGS. 6B, 7B, 8B, 9B, 10B, 11B, 12B, 13B, 14B, 15B, 16B, 17B, 18B and 19B.

According to a non-limiting embodiment of the present invention, the conditions of the epitaxial growth process for the source/drain regions 116-1, 116-2 and 116-3 (collectively “source/drain regions 116”) and source/drain region 117 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr.

The source/drain regions 116 and 117 may be suitably doped, such as by using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl).

In non-limiting illustrative embodiments, the source/drain regions 116 and other source/drain regions for NFETs can comprise in-situ phosphorous doped (ISPD) silicon or Si:C for n-type devices, and the source/drain region 117 and other source/drain regions for PFETs can comprise in-situ boron doped (ISBD) silicon germanium for p-type devices, at concentrations of about 1×10¹⁹/cm³ to about 3×10²¹/cm³. By “in-situ,” it is meant that the dopant that dictates the conductivity type of the doped layer is introduced during the process step, e.g., epitaxial deposition, which forms the doped layer.

Referring to FIGS. 6A and 6B, gate regions 121 and corresponding cap layers 124 and an ILD layer 130 are formed. The cap layers 114 and dummy gate regions 111 are selectively removed to create vacant areas where gate regions 121 and cap layers 124 will be formed in place of the dummy gate regions 111. The selective removal can be performed using, for example hot ammonia to remove the dummy gate regions 111. In illustrative embodiments, each gate region 121 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate regions 121 each include a metal gate portion including a work-function metal (WFM) layer, including but not necessarily limited to, for a PFET, titanium nitride (TiN), tantalum nitride (TaN) or ruthenium (Ru), and for an NFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired. The cap layers 124 comprise, but are not necessarily limited to, silicon SiN, SiBN, SiBCN or SiOCN. According to an embodiment of the present invention, the cap layers 124 are deposited using, for example, deposition techniques including, but not limited to, CVD, PECVD, RFCVD, PVD, ALD, MLD, MBD, PLD, LSMCD, sputtering, and/or plating, followed by a planarization process, such as, for example, CMP.

An ILD layer 130 is deposited to fill in portions on and around the buried dielectric layer 102, the source/drain regions 116 and 117 and the gate regions 121. The ILD layer 130 is deposited using deposition techniques such as, for example, CVD, PECVD, RFCVD, PVD, ALD, MBD, PLD, and/or LSMCD, followed by a planarization process, such as, CMP. The ILD layer 130 may comprise, for example, SiOₓ, SiOC, SiOCN or some other dielectric material.

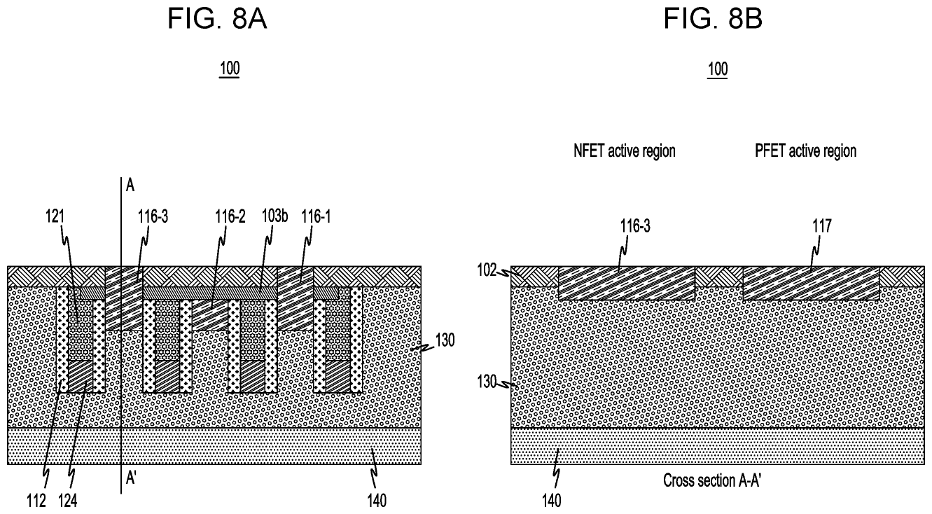

Referring to FIGS. 7A and 7B, the resulting structure from FIGS. 6A and 6B is attached to another semiconductor substrate 140 and rotated. Using the other semiconductor substrate 140 as, for example, a carrier wafer, the FIG. 6A and FIG. 6B structures may be “flipped” (e.g., rotated 180 degrees) so that the structures are inverted. The other semiconductor substrate 140 may comprise the same or a similar material to that of the semiconductor substrate 101. Referring to FIGS. 8A and 8B, the semiconductor substrate 101 is removed from the backside. The removal process, which can comprise etching of the semiconductor substrate 101, stops at the buried dielectric layer 102. As can be seen, following removal of the semiconductor substrate 101, the base portions, and more particularly, bottom surfaces, of the source/drain regions 116-1, 116-3 and 117 are exposed.

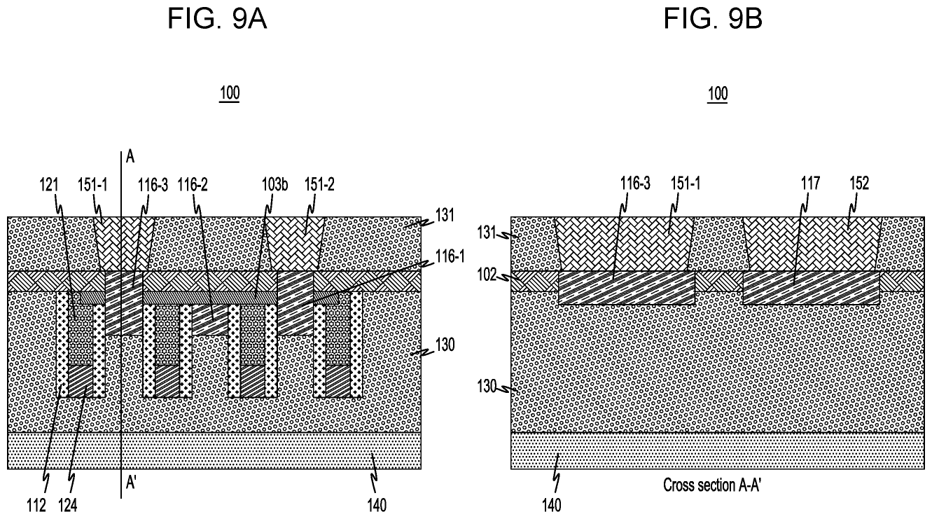

Referring to FIGS. 9A and 9B, a second ILD layer 131 is formed on the FIGS. 8A and 8B structures, and source/drain contacts 151-1, 151-2 and 152 are respectively formed on the source/drain regions 116-3, 116-1 and 117. In more detail, the second ILD layer 131, which can be similar to the ILD layer 130, is deposited on exposed portions of the buried dielectric layer 102 and the source/drain regions 116 and 117. The second ILD layer 131 is deposited using the same or similar deposition techniques and comprises the same or similar materials as those of the ILD layer 130. Following formation of the second ILD layer 131, portions of the semiconductor structure 100 are masked (e.g., with a hardmask (not shown)). At unmasked portions corresponding to where the source/drain contacts 151-1, 151-2 and 152 are to be formed, openings (e.g., contact trenches) are formed by removing parts of the second ILD layer 131 over the source/drain regions 116-3, 116-1 and 117. The contact trenches are formed using, for example, a dry etching process using a RIE or ion beam etch (IBE) process, a wet chemical etch process or a combination of these etching processes. The contact trenches expose corresponding source/drain regions 116-3, 116-1 and 117.

The source/drain contacts 151-1, 151-2 and 152 are formed in the contact trenches. The source/drain contacts 151-1, 151-2 and 152 contact and are formed on base portions (e.g., bottom surfaces) of source/drain regions 116-3, 116-1 and 117, respectively. The source/drain contacts 151-1, 151-2 and 152 each comprise, for example, a silicide liner such as Ti, Ni, NiPt, an adhesion metal liner, such as TiN, and a low resistance conductor such as, but not necessarily limited to tungsten, cobalt, ruthenium, etc., and can be deposited using, for example, a deposition technique such as CVD, PECVD, RFCVD, PVD, ALD, MBD, PLD, LSMCD, sputtering and/or plating. As can be seen, the source/drain contacts 151-1, 151-2 and 152 are on a backside of the semiconductor structure 100. As explained in more detail herein below, the source/drain contacts 151-1 and 151-2 are ground (GND) contacts, and the source/drain contact 152 is a supply voltage (VDD) (also referred to herein as a “power supply”) contact.

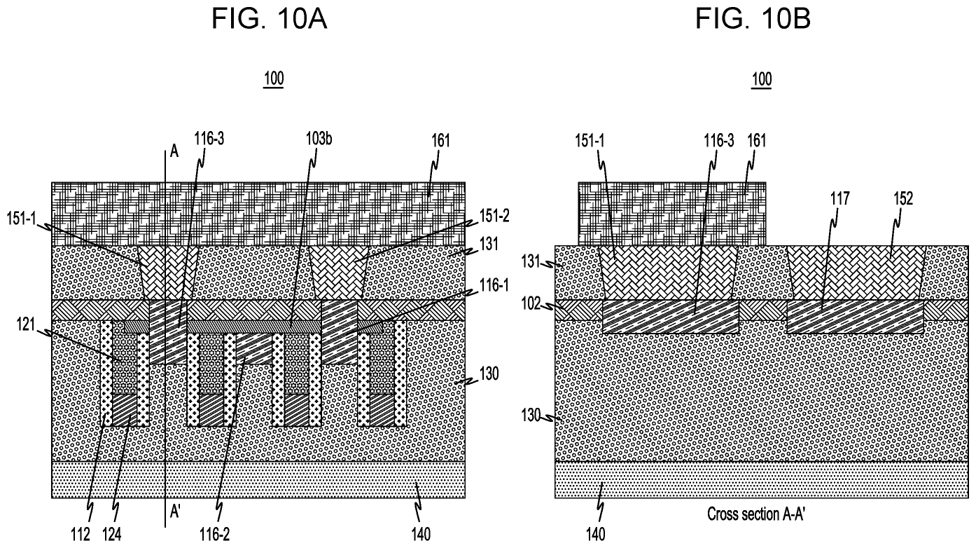

Referring to FIGS. 10A and 10B, a ground line 161 is formed on the semiconductor structure 100 of FIGS. 9A and 9B. In illustrative embodiments, the ground line 161 is a backside rail (e.g., power rail) that may be part of a backside power delivery network (BSPDN). In an embodiment, the ground line 161 is formed by depositing conductive material on the second ILD layer 131 and patterning the deposited conductive material. The conductive material includes, for example, electrically conductive material including, but not necessarily limited to, tungsten, cobalt, zirconium, tantalum, titanium, aluminum, ruthenium, and/or copper. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP. The ground line 161 provides a ground connection (e.g., 0 volts). The ground line 161 is formed on and contacts the source/drain contacts 151-1 and 151-2 to provide a ground connection to source/drain regions 116-3 and 116-1.

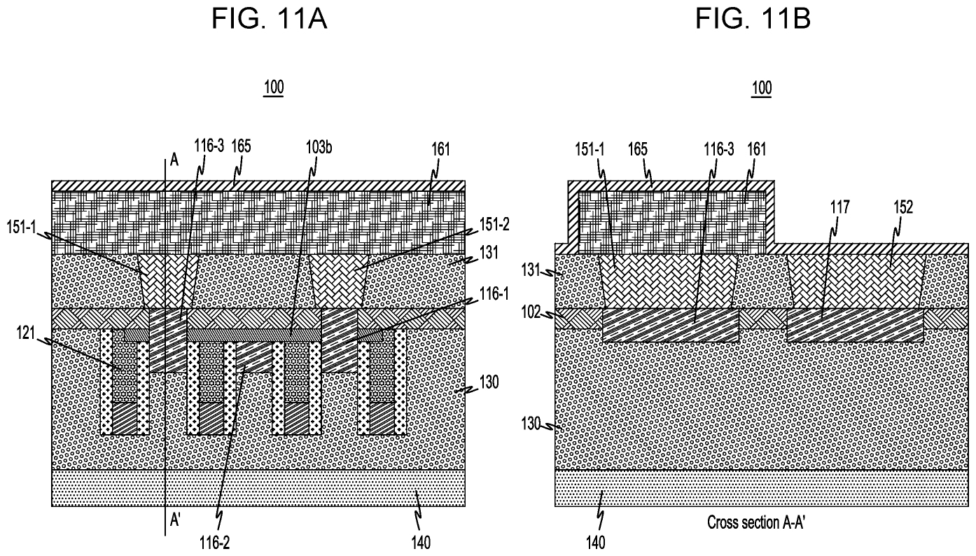

Referring to FIGS. 11A and 111B, a dielectric layer 165 is formed on the FIGS. 10A and 10B structures, including on top and side surfaces of the ground line 161 and on exposed surfaces of the second ILD layer 131 and source/drain contact 152. According to an embodiment, the dielectric layer 165 comprises a high-K dielectric layer deposited to a thickness of about 1 nanometer to about 20 nanometers. The dielectric layer 165 is deposited using a deposition technique such as, for example, CVD, PECVD, PVD, ALD, MBD, PLD and/or LSMCD.

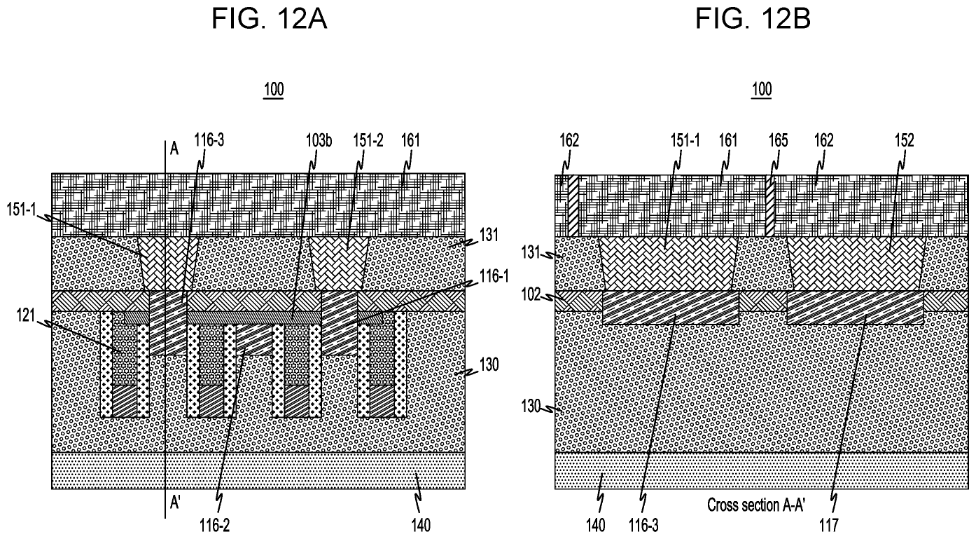

Referring to FIGS. 12A and 12B, horizontal portions of the dielectric layer 165 are removed using, for example, a directional etching process such as a directional RIE process. Then, as shown in FIG. 12B, a supply voltage line 162 (e.g., power supply line) is deposited on the exposed portions of the second ILD layer 131 and source/drain contact 152. In illustrative embodiments, like the ground line 161, the supply voltage line 162 is a backside rail (e.g., power rail) that may be part of a BSPDN. BSPDN layers include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents backend of line (BEOL) routing congestion, resulting in power performance benefits.

In an embodiment, the supply voltage line 162 is formed by depositing conductive material on the exposed portions of the second ILD layer 131 and source/drain contact 152, and performing a planarization process such as, for example, CMP, to remove excess portions of the conductive material of the supply voltage line 162 from on top of the ground line 161 and remaining portions of the dielectric layer 165. The conductive material includes, for example, electrically conductive material including, but not necessarily limited to, tungsten, cobalt, zirconium, tantalum, titanium, aluminum, ruthenium, and/or copper. Deposition of the conductive material can be performed using one or more deposition techniques, including, but not necessarily limited to, CVD, PECVD, PVD, ALD, MBD, PLD, LSMCD, and/or spin-on coating, followed by planarization. The supply voltage line 162 provides a power connection (e.g., supply voltage (VDD)). The supply voltage line 162 is formed on and contacts the source/drain contact 152 to provide a supply voltage connection to source/drain region 117. The portions of the dielectric layer 165 separating the ground and supply voltage lines 161 and 162 from each other are disposed between the ground and supply voltage lines 161 and 162 on opposing sidewalls of the ground and supply voltage lines 161 and 162. A vertical thickness of the ground and supply voltage lines 161 and 162 can be in the range of about 10 nanometers to about 100 nanometers. Capacitance increases with a thickness of the ground and supply voltage lines 161 and 162.

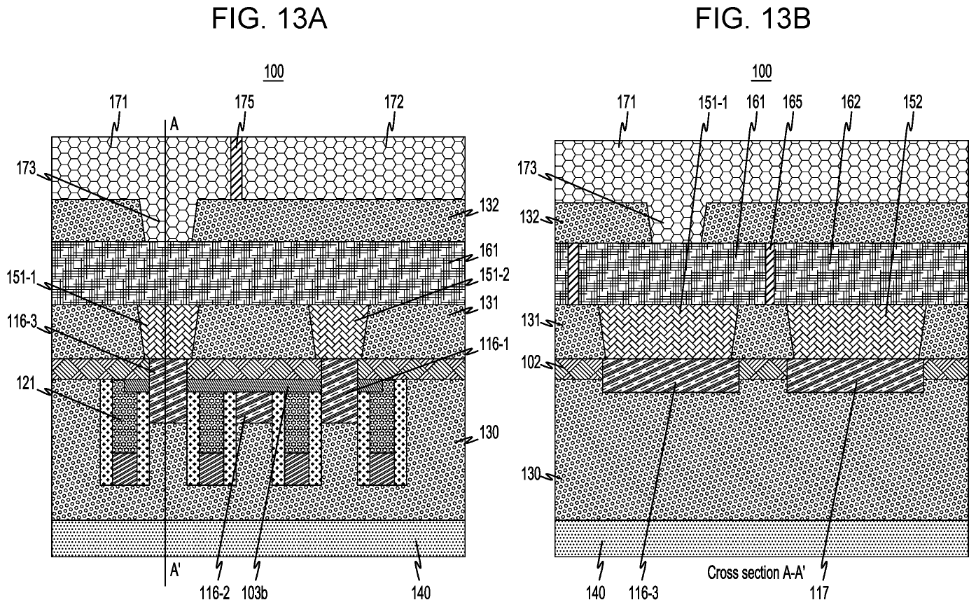

Referring to FIGS. 13A and 13B, a third ILD layer 132 is formed on the ground and supply voltage lines 161 and 162. The third ILD layer 132, which can be similar to the ILD layer 130 and second ILD layer 131, is deposited on top surfaces of the ground and supply voltage lines 161 and 162, and top surfaces of the portions of the dielectric layer 165 isolating the ground and supply voltage lines 161 and 162 from each other. The third ILD layer 132 is deposited using the same or similar deposition techniques and comprises the same or similar materials as those of the ILD layer 130 and second ILD layer 131. Following formation of the third ILD layer 132, another metallization level comprising a ground line 171 and a supply voltage line 172 is formed in addition to the metallization level comprising the ground and supply voltage lines 161 and 162. The metallization level comprising the ground and supply voltage lines 171 and 172 is formed on the third ILD layer 132. As shown in FIG. 13A, similar to the dielectric layer 165, the ground and supply voltage lines 171 and 172 are isolated from each other by a dielectric layer 175 disposed between the ground and supply voltage lines 171 and 172 on opposing sidewalls of the ground and supply voltage lines 171 and 172. Like the dielectric layer 165, the dielectric layer 175 comprises a high-K dielectric material. In an illustrative embodiment, the ground and supply voltage lines 171 and 172 are in a different plane from the ground and supply voltage lines 161 and 162 and are oriented orthogonally to the ground and supply voltage lines 161 and 162. In other words, a length of the ground and supply voltage lines 171 and 172 is perpendicular to a length of the ground and supply voltage lines 161 and 162.

A via 173 formed in and through the third ILD layer 132 connects the ground line 171 to the ground line 161. The via comprises, for example, the same or a similar conductive material to that of the ground and supply voltage lines 171 and 172. The via 173 is electrically isolated from the supply voltage lines 162 and 172.

In similar arrangements to those shown in FIGS. 10A-13B, if the type of the source/drain regions 116 and 117 were swapped (e.g., p-type instead of n-type in the case of source/drain regions 116 or n-type instead of p-type in the case of source/drain regions 117), supply voltage lines (e.g., power supply lines) having the same configuration as the ground lines 161 and 171 would be formed in place of the ground lines 161 and 171, and ground lines having the same configuration as the supply voltage lines 162 and 172 would be formed in place of the supply voltage lines 162 and 172.

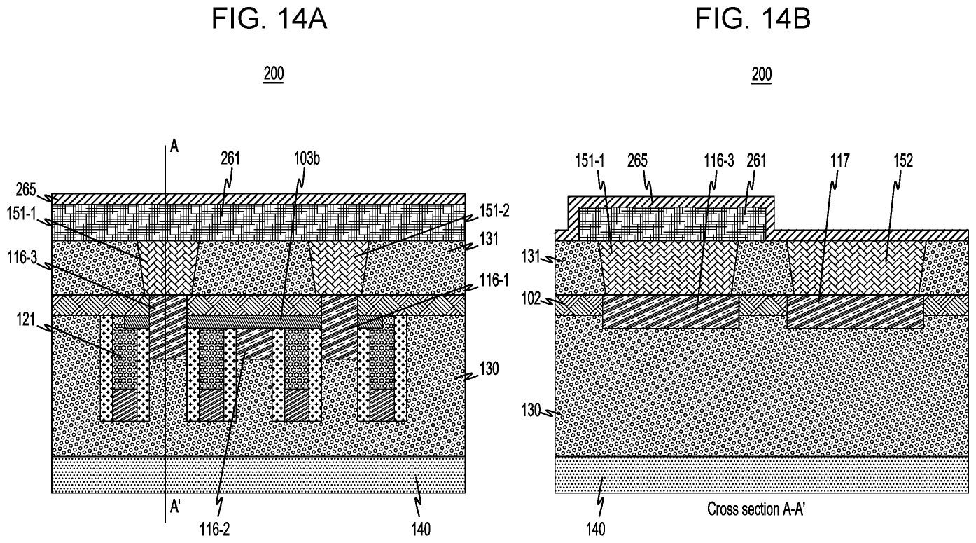

Referring to FIGS. 14A and 14B, in another illustrative embodiment, following from FIGS. 9A and 9B, a semiconductor structure 200 is formed. The processing through FIG. 9B is the same as that for the semiconductor structure 100. As shown in FIGS. 14A and 14B, a ground line 261 is formed on the semiconductor structure 100 of FIGS. 9A and 9B. The ground line 261 is similar to the ground line 161, but is thinner than the ground line 161. For example, a thickness of the ground line 261 is in the range of 10 nanometers to about 100 nanometers. In illustrative embodiments, like the ground line 161, the ground line 261 is a backside rail (e.g., power rail) that may be part of a BSPDN. In an embodiment, the ground line 261 is formed by depositing conductive material on the second ILD layer 131 and patterning the deposited conductive material. The conductive material includes, for example, the same or a similar conductive material to that of the ground line 161. Deposition of the conductive material can be performed using the same or similar techniques to those used for the ground line 161. The ground line 261 provides a ground connection (e.g., 0 volts). The ground line 261 is formed on and contacts the source/drain contacts 151-1 and 151-2 to provide a ground connection to source/drain regions 116-3 and 116-1.

A dielectric layer 265 similar to the dielectric layer 165 is formed on top and side surfaces of the ground line 261 and on exposed surfaces of the second ILD layer 131 and source/drain contact 152. According to an embodiment, the dielectric layer 265 comprises a high-K dielectric layer deposited to a thickness of about 1 nanometer to about 20 nanometers. The dielectric layer 265 is deposited using a deposition technique such as, for example, CVD, PECVD, PVD, ALD, MBD, PLD and/or LSMCD.

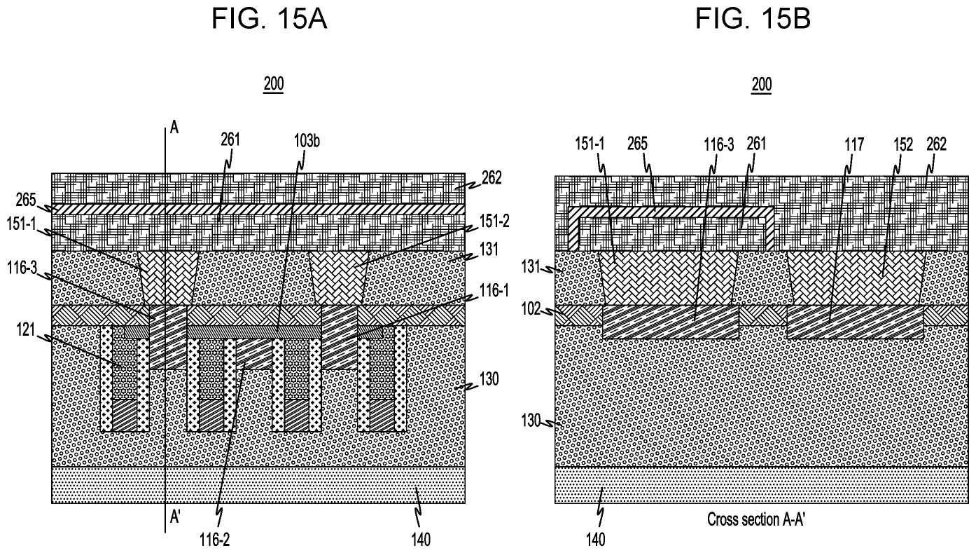

Referring to FIGS. 15A and 15B, portions of the dielectric layer on the second ILD layer 131 and source/drain contact 152 are removed using lithography techniques. As can be seen, the dielectric layer 265 remains on a top surface of the ground line 261 and on side surfaces of the ground line 261. Then, as shown in FIGS. 15A and 15B, a supply voltage line 262 (e.g., power supply line) is deposited on a top surface of the ground line 261 comprising the dielectric layer 265 thereon, and on the exposed portions of the second ILD layer 131 and source/drain contact 152. In illustrative embodiments, like the ground line 261, the supply voltage line 262 is a backside rail (e.g., power rail) that may be part of a BSPDN.

In an embodiment, the supply voltage line 262 is formed by depositing conductive material on a top surface of the ground line 261 comprising the dielectric layer 265 thereon, and on the exposed portions of the second ILD layer 131 and source/drain contact 152. The conductive material includes, for example, the same or a similar conductive material to that of the supply voltage line 162. Deposition of the conductive material can be performed using one or more deposition techniques, including, but not necessarily limited to, CVD, PECVD, PVD, ALD, MBD, PLD, LSMCD, and/or spin-on coating. Like the supply voltage line 162, the supply voltage line 262 provides a power connection (e.g., supply voltage (VDD)). The supply voltage line 262 is formed on and contacts the source/drain contact 152 to provide a supply voltage connection to source/drain region 117. The portions of the dielectric layer 265 isolating the ground and supply voltage lines 261 and 262 from each other are disposed: (i) between the ground and supply voltage lines 261 and 262 on opposing sidewalls of the ground and supply voltage lines 261 and 262; and (ii) between the ground and supply voltage lines 261 and 262 on a top surface of the ground line 261 and on a bottom surface of the supply voltage line 262 opposite the top surface of the ground line 261. As can be seen in FIG. 15B, portions of the dielectric layer 265 disposed on lateral sides of the ground line 261 are perpendicular to a portion of the dielectric layer 265 disposed on a top surface of the ground line 261.

The supply voltage line 262 is stacked on the ground line 261 and extends along sides of the ground line 261 down to a top surface of the second ILD layer 131 and the source/drain contact 152. A combined vertical thickness of the ground and supply voltage lines 261 and 262 can be in the range of about 10 nanometers to about 100 nanometers. Capacitance increases with thicknesses of the ground and supply voltage lines 261 and 262.

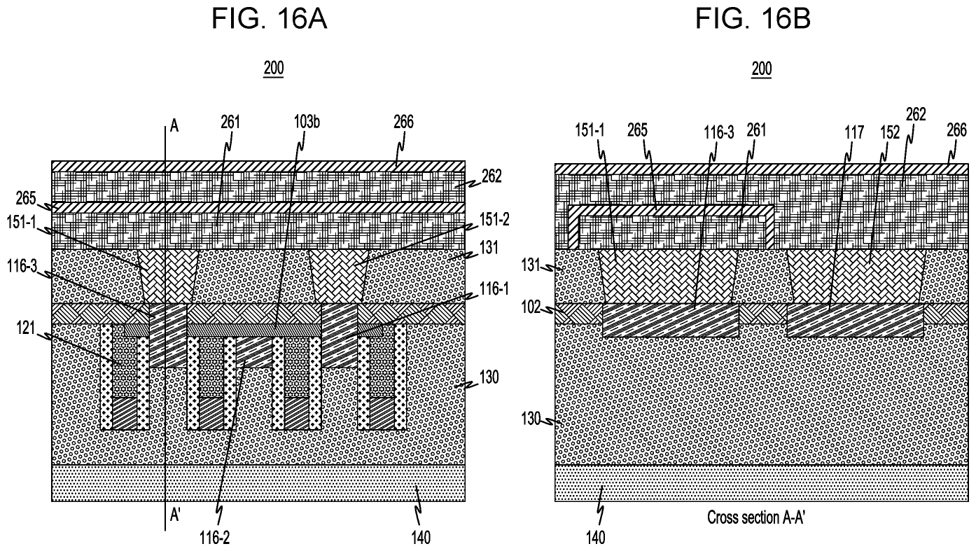

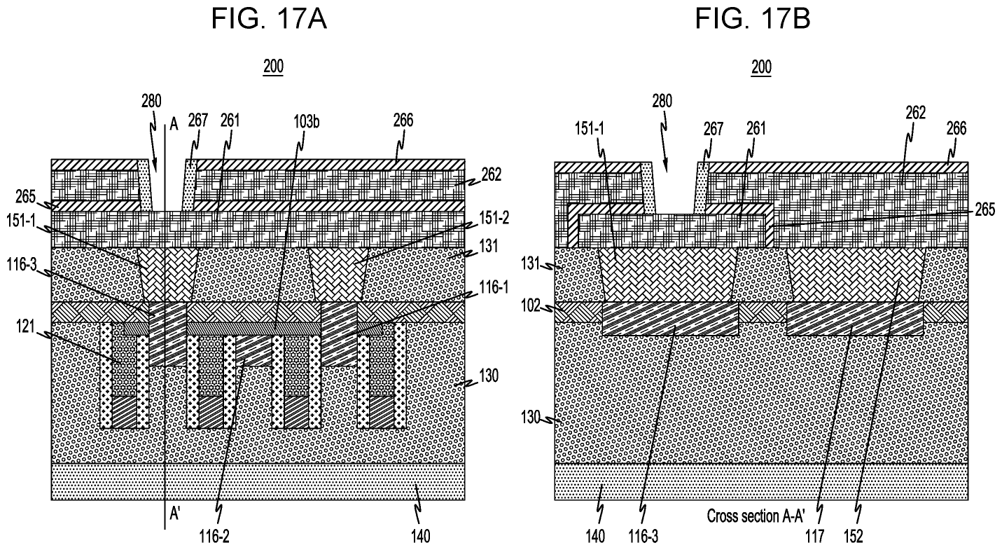

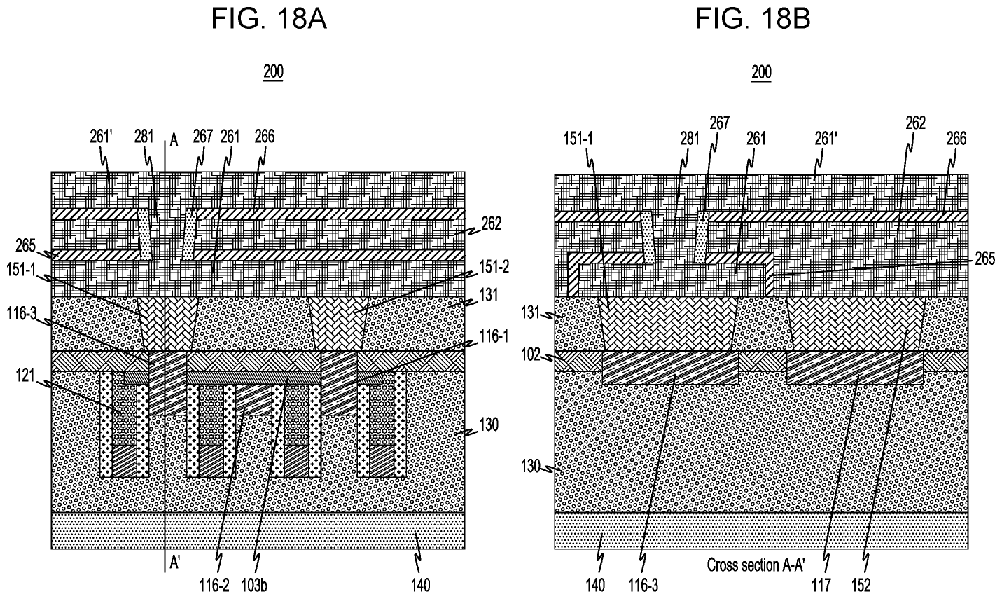

Referring to FIGS. 16A and 16B, a second dielectric layer 266 similar to the dielectric layer 265 is formed on a top surface of the supply voltage line 262. Like the dielectric layer 265, the second dielectric layer 266 comprises a high-K dielectric layer deposited to a thickness of about 1 nanometer to about 20 nanometers, and is deposited using a deposition technique such as, for example, CVD, PECVD, PVD, ALD, MBD, PLD and/or LSMCD. Referring to FIGS. 17A and 17B, a via opening 280 is formed through a portion of the second dielectric layer 266, a portion of the supply voltage line 262 and a portion of the dielectric layer 265 to expose a portion of the top surface of the ground line 261. The via opening 280 is formed using, for example, a RIE process. The via opening 280 includes dielectric layers 267 on sidewalls of the via opening 280 so that the resulting via 281 (see FIGS. 18A and 18B) is isolated from the supply voltage line 262. Like the dielectric layers 265 and 266, the dielectric layers 267 comprise a high-K dielectric layer deposited to a thickness of about 1 nanometer to about 20 nanometers, and are deposited using a deposition technique such as, for example, CVD, PECVD, PVD, ALD, MBD, PLD and/or LSMCD.

Referring to FIGS. 18A and 18B, a second ground line 261′ is formed on the semiconductor structure 200 of FIGS. 17A and 17B. The second ground line 261′ is formed by depositing conductive material on a top surface of the supply voltage line 262 comprising the second dielectric layer 266 thereon, and in the via opening 280 onto the exposed portion of ground line 261. The conductive material is deposited on the dielectric layers 267 in the via opening 280 to fill in a remaining portion of the via opening 280 and form the via 281. The via 281 connects the second ground line 261′ to the ground line 261. The conductive material includes, for example, the same or a similar conductive material to that of the ground line 261. Deposition of the conductive material can be performed using one or more deposition techniques, including, but not necessarily limited to, CVD, PECVD, PVD, ALD, MBD, PLD, LSMCD, and/or spin-on coating. Like the ground line 261, the second ground line 261′ provides a ground connection (e.g., 0 volts).

The second ground line 261′ is stacked on the supply voltage line 262. The portions of the second dielectric layer 266 isolating the second ground line 261′ from the supply voltage line 262 are disposed between the second ground line 261′ and the supply voltage line 262 on a top surface of the supply voltage line 262 and on a bottom surface of the second ground line 261′ opposite the top surface of the supply voltage line 262.

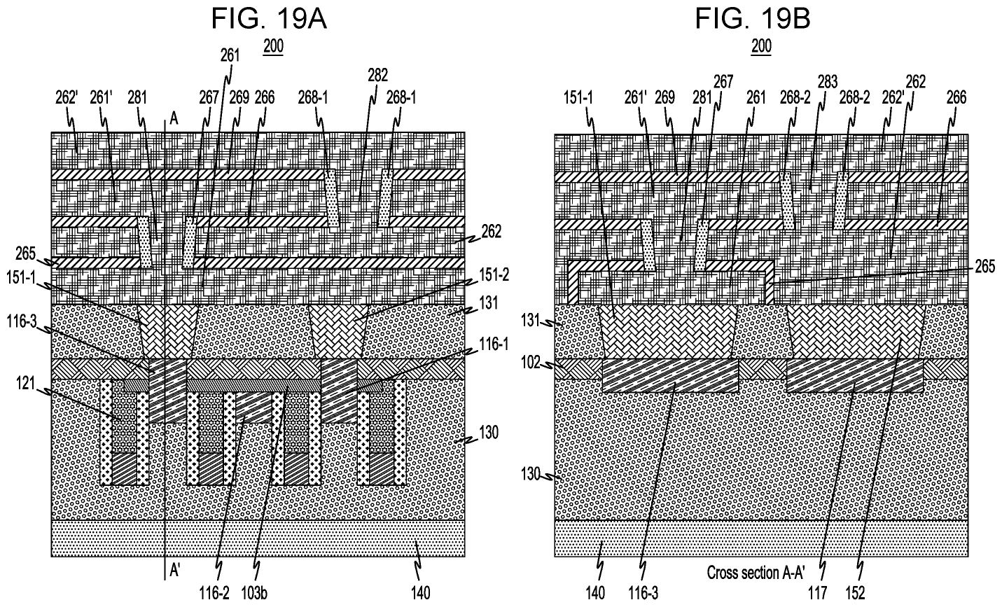

Referring to FIGS. 19A and 19B, a second supply voltage line 262′ and vias 282 and 283 are formed on the semiconductor structure 200 of FIGS. 18A and 18B. The second supply voltage line 262′ is formed by depositing conductive material on a top surface of the second ground line 261′ comprising a third dielectric layer 269 thereon, and into previously formed via openings (like via opening 280) onto exposed portions of the supply voltage line 262. Like the dielectric layer 265 and the second dielectric layer 266, the third dielectric layer 269 comprises a high-K dielectric layer deposited to a thickness of about 1 nanometer to about 20 nanometers, and is deposited using a deposition technique such as, for example, CVD, PECVD, PVD, ALD, MBD, PLD and/or LSMCD. The conductive material is deposited on dielectric layers 268-1 and 268-2 in the via openings to fill in remaining portions of the via openings and form the vias 282 and 283. The dielectric layers 268-1 and 268-2 are on sidewalls of the via openings so that the vias 282 and 283 are isolated from the second ground line 261′. Like the dielectric layers 267, the dielectric layers 268-1 and 268-2 comprise a high-K dielectric layer deposited to a thickness of about 1 nanometer to about 20 nanometers, and are deposited using a deposition technique such as, for example, CVD, PECVD, PVD, ALD, MBD, PLD and/or LSMCD.

The vias 282 and 283 connect the second supply voltage line 262′ to the supply voltage line 262. The conductive material includes, for example, the same or a similar conductive material to that of the supply voltage line 262. Deposition of the conductive material can be performed using one or more deposition techniques, including, but not necessarily limited to, CVD, PECVD, PVD, ALD, MBD, PLD, LSMCD, and/or spin-on coating. Like the supply voltage line 262, the second supply voltage line 262′ provides a power connection (e.g., supply voltage (VDD)).

The second supply voltage line 262′ is stacked on the second ground line 261′. The portions of the third dielectric layer 269 isolating the second supply voltage line 262′ from the second ground line 261′ are disposed between the second ground line 261′ and the second supply voltage line 262′ on a top surface of the second ground line 261′ and on a bottom surface of the second supply voltage line 262′ opposite the top surface of the second ground line 261′.

In similar arrangements to those shown in FIGS. 14A-19B, if the type of the source/drain regions 116 and 117 were swapped (e.g., p-type instead of n-type in the case of source/drain regions 116 or n-type instead of p-type in the case of source/drain regions 117), supply voltage lines (e.g., power supply lines) having the same configuration as the ground lines 261 and 261′ would be formed in place of the ground lines 261 and 261′, and ground lines having the same configuration as the supply voltage lines 262 and 262′ would be formed in place of the supply voltage lines 262 and 262′.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. An example integrated circuit includes one or more semiconductor devices with the above-described contact configurations and transistors stacked in a staggered configuration.

As noted above, illustrative embodiments correspond to methods for forming power supply and ground lines on a backside of a semiconductor device and at least one dielectric layer disposed between the power supply and ground lines, along with illustrative apparatus, systems and devices formed using such methods. As CMOS technology continues to scale, cell track height has decreased. An issue with low-track logic cells is wire-ability, especially in the case of a stacked FET architecture. As the power rails occupy relatively large areas, there is little room for routing input and output wires. Locating the ground and power supply lines to a backside of a chip mitigates the wire-ability issue.

Power rails can be made relatively wide such that IR drop can be low, and large capacitance between VDD and ground is desired to stabilize the power supply. The embodiments advantageously provide backside power rails with VDD and GND lines separated by relatively thin high-k dielectric layers to provide high capacitance, and function like local decoupling capacitors. In illustrative embodiments, the backside power rails with VDD and GND lines separated by relatively thin high-k dielectric layers are provided on the full backside of a chip and/or all layers of a power delivery grid. The embodiments may be further disposed on the backside of a three-dimensional stacked transistor architecture.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a transistor structure comprising a plurality of source/drain regions, wherein base portions of the plurality of source/drain regions correspond to a second side of the semiconductor device opposite to a first side of the semiconductor device;
a plurality of metal lines disposed on the second side of the semiconductor device, wherein the plurality of metal lines comprise at least a first metal line and a second metal line; and
at least one dielectric layer disposed between the first metal line and the second metal line.

2. The semiconductor device of claim 1, further comprising a plurality of contacts formed on the base portions respective ones of the plurality of source/drain regions, wherein at least one of the first metal line and the second metal line is connected to one or more of the plurality of contacts.

3. The semiconductor device of claim 2, wherein at least one of the first metal line and the second metal line is disposed on the one or more of the plurality of contacts.

4. The semiconductor device of claim 1, wherein the second side comprises a backside of the semiconductor device and the first side comprises a frontside of the semiconductor device.

5. The semiconductor device of claim 1, wherein the at least one dielectric layer comprises a high-K dielectric material.

6. The semiconductor device of claim 1, wherein the first metal line comprises a ground line and the second metal line comprises a supply voltage line.

7. The semiconductor device of claim 1, wherein the at least one dielectric layer is disposed on a sidewall of the first metal line and on a sidewall of the second metal line opposite the sidewall of the first metal line.

8. The semiconductor device of claim 1, wherein the at least one dielectric layer is disposed on a top surface of the first metal line and on a bottom surface of the second metal line opposite the top surface of the first metal line.

9. The semiconductor device of claim 1, wherein the second metal line is stacked on the first metal line.

10. The semiconductor device of claim 9, wherein the first metal line comprises a ground line and the second metal line comprises a supply voltage line.

11. The semiconductor device of claim 1, wherein the at least one dielectric layer is disposed on a first surface of at least one of the plurality of metal lines and on a second surface of the at least one of the plurality of metal lines, wherein the second surface is perpendicular to the first surface.

12. The semiconductor device of claim 1, wherein the plurality of metal lines further comprise at least a third metal line stacked on top of at least one of the first metal line and the second metal line.

13. The semiconductor device of claim 12, wherein third metal line is connected to one of the first metal line and the second metal line through at least one via.

14. The semiconductor device of claim 12, wherein the at least one via comprises a dielectric layer on a sidewall of the at least one via.

15. A semiconductor device, comprising:
a plurality of metal lines disposed on a backside of the semiconductor device, wherein the plurality of metal lines comprise at least a power supply line and a ground line; and
at least one dielectric layer disposed between the power supply line and the ground line.

16. The semiconductor device of claim 15, wherein the at least one dielectric layer is disposed on a sidewall of the power supply line and on a sidewall of the ground line opposite the sidewall of the power supply line.

17. The semiconductor device of claim 15, wherein the at least one dielectric layer is disposed on a top surface of the power supply line and on a bottom surface of the ground line opposite the top surface of the power supply line.

18. A semiconductor device, comprising:
a transistor structure, wherein a base portion of the transistor structure corresponds to a second side of the semiconductor device opposite to a first side of the semiconductor device;
a plurality of conductive lines disposed on the second side of the semiconductor device; and
at least one dielectric layer disposed between at least two conductive lines of the plurality of conductive lines.

19. The semiconductor device of claim 18, wherein the at least one dielectric layer is disposed on a sidewall of a first conductive line of the at least two conductive lines and on a sidewall of a second conductive line of the at least two conductive lines opposite the sidewall of the first conductive line.

20. The semiconductor device of claim 18, wherein the at least one dielectric layer is disposed on a top surface of a first conductive line of the at least two conductive lines and on a bottom surface of a second conductive line of the at least two conductive lines opposite the top surface of the first conductive line.
